(19) United States
(12) Patent Application Publication
(10) Pub. No.: US 2016/0014905 A1
(43) Pub. Date: Jan. 14, 2016

(54) LAMINATE FOR ELECTRODE PATTERN PRODUCTION, PRODUCTION METHOD THEREOF, TOUCH PANEL SUBSTRATE, AND IMAGE DISPLAY DEVICE

(71) Applicant: NITTO DENKO CORPORATION, Osaka (JP)

(72) Inventor: Makoto Tsunekawa, Ibaraki-shi (JP)

(73) Assignee: NITTO DENKO CORPORATION, Osaka (JP)

(21) Appl. No.: 14/791,817

(22) Filed: Jul. 6, 2015

(30) Foreign Application Priority Data
Jul. 10, 2014 (JP) 2014-142314

(51) Int. Cl. H05K 3/00; G06F 1/16; G06F 3/041; B32B 37/14; H05K 1/03

(52) U.S. Cl. CPC H05K 3/0061; B32B 37/14; H05K 1/03; G06F 3/0412; G06F 1/16; B32B 2457/208; H05K 2201/0108; G06F 2203/04103

(57) ABSTRACT

A laminate for electrode pattern production includes an underlying metal disposed on one face in the thickness direction of the transparent substrate, wherein the one face in the thickness direction thereof has an arithmetical roughness Ra calculated in conformity with JIS B 0601 of 100 nm or more; and an electrode layer disposed on the one face in the thickness direction of the underlying metal.

### CROSS-REFERENCE TO RELATED APPLICATION

The present application claims priority from Japanese Patent Application No. 2014-142314 filed on Jul. 10, 2014, the content of which is herein incorporated by reference into this application.

### BACKGROUND OF THE INVENTION

1. Field of the Invention

The present invention relates to a laminate for electrode pattern production, a production method thereof, a touch panel substrate, and an image display device; in particular, the present invention relates to a laminate for electrode pattern production, a method for producing a laminate for electrode pattern production, a touch panel substrate produced from the laminate for electrode pattern production, and an image display device including the touch panel substrate.

2. Description of Related Art

Conventionally, it has been known that an image display device such as a liquid crystal display device includes a touch panel substrate wherein a metal layer including wires is disposed on the front face and the back face of the touch panel substrate.

There are concerns with such wires, because such wires have metallic luster, which causes inferior visibility of liquid crystal display devices.

Thus, it has been known, as a laminate for touch panel substrate production, for example, a laminate 50 including a first black layer 56, a first metal layer 55, a substrate 51, a second black layer 57, and a second metal layer 58 in this sequence, as shown in FIG. 9C.

To produce such a laminate 50, for example, a first substrate 51, on which a first metal layer 55 and a first black layer 56 are sequentially laminated on the front face shown in FIG. 9A, and a second substrate 49, on which a second metal layer 58 and a first black layer 57 are sequentially laminated on the front face shown in FIG. 9B, are bonded, so as to sandwich the first substrate 51 with the first metal layer 55 and the second metal layer 58 in the front and back directions, as shown in FIG. 9C.

In such a laminate 50, the first black layer 56 can prevent inferior visibility of the display 40 from the front side (viewer side) caused by metallic luster of the front face of the first conductor layer 55, and at the same time, the second black layer 57 can prevent inferior visibility of the display 40 from the front side (viewer side) caused by metallic luster of the front face of the second conductor layer 58.

However, in this method, two substrates (first substrate 51 and second substrate 49) have to be prepared, which involves labor to that extent.

Thus, for example, Japanese Unexamined Patent Publication No. 2013-129183 has proposed a method in which two metal layers and two black layers are disposed on both sides of one substrate.

With the method in Japanese Unexamined Patent Publication No. 2013-129183, first, as shown in FIG. 10A, the substrate 51 is prepared, and then the second black layer 57 is formed on the back face of the substrate 51 by, for example, processes such as sputtering or plating, and then, as shown in FIG. 10B, the first conductor layer 55 and the second conductor layer 58 are formed on the front face of the substrate 51 and the back face of the second black layer 57, respectively. Thereafter, as shown in FIG. 10C, the first black layer 56 is formed on the front face of the first conductor layer 55 by the above-described process.

### SUMMARY OF THE INVENTION

However, in the method of Japanese Unexamined Patent Publication No. 2013-129183, two black layers of the second black layer 57 and the first black layer 56 are formed in separate steps, that is, in a step (ref: FIG. 10A) before the step of forming the first conductor layer 55 and the second conductor layer 58, and a step (ref: FIG. 10C) thereafter. Thus, there are disadvantages in that the laminate 50 is produced by troublesome steps.

An object of the present invention is to provide a laminate for electrode pattern production, and also a method for producing a laminate for electrode pattern production for production of a touch panel substrate with a simple method, a laminate for electrode pattern production produced by the method, and a touch panel substrate produced therefrom, and an image display device including the touch panel substrate and having excellent visibility.

The present invention is as follows:
[1]

A laminate for electrode pattern production including: a transparent substrate; an underlying metal disposed on one face in a thickness direction of the transparent substrate, wherein the one face in the thickness direction of the underlying metal has an arithmetical roughness Ra calculated in conformity with JIS B 0601 of 100 nm or more; and an electrode layer disposed on the one face in the thickness direction of the underlying metal.

[2]

The laminate for electrode pattern production of [1] above, wherein the underlying metal includes agglomerated particles made of agglomerated primary particles of metal particles, and the agglomerated particles have an average particle size of 30.0 nm or more.

[3]

The laminate for electrode pattern production of [1] or [2] above, wherein the luminous reflectance (value Y) is 20.0% or less, the luminous reflectance measured by using a spectrophotometer, irradiating the underlying metal from the other side in the thickness direction of the transparent substrate through the transparent substrate, and scanning with a wavelength of 300 nm to 1300 nm.

[4]

The laminate for electrode pattern production of any one of [1] to [3] above, wherein the underlying metal is provided by modifying the one face in the thickness direction of the transparent substrate with one selected from the group consisting of active energy rays, plasma, and laser, and then electrolessly plating the modified transparent substrate.

[5]

The laminate for electrode pattern production of any one of [1] to [4] above, wherein the underlying metal is also disposed on the other face in the thickness direction of the transparent substrate, and

of the two underlying metals, at least one face in the thickness direction of the underlying metal disposed at one side in the thickness direction of the transparent substrate has an arithmetical roughness Ra of 100 nm or more.

[6]

A touch panel substrate including an electrode pattern formed by patterning the electrode layer and the underlying metal of the laminate for electrode pattern production of any one of [1] to [5] above.

[7]

An image display device including the touch panel substrate of [6] above, and an image display element disposed on one side in the thickness direction of the touch panel substrate.

[8]

The image display device of [7] above, wherein the image display element is a liquid crystal display module.

[9]

A method for producing a laminate for electrode pattern production includes,
preparing a transparent substrate,
modifying one face in the thickness direction of the transparent substrate,
disposing an underlying metal on the modified one face in the thickness direction of the transparent substrate, and
disposing an electrode layer on the one face in the thickness direction of the underlying metal.
   [10]

The method for producing a laminate for electrode pattern production of [9] above, wherein in the step of modifying the one face in the thickness direction of the transparent substrate, the transparent substrate is modified by one selected from the group consisting of active energy rays, plasma, and laser.

In a laminate for electrode pattern production and a touch panel substrate of the present invention, just by a simple configuration of setting the arithmetical roughness Ra of the one face in the thickness direction of the underlying metal for providing an electrode layer to a specific lower limit value or more, without providing a black layer on one face in the thickness direction of the transparent substrate, the reflectance of the underlying metal can be set to low.

Therefore, in an image display device including a touch panel substrate of the present invention, decrease in visibility of the image display element caused by metallic luster of the underlying metal can be prevented, while a simple configuration can be achieved.

In a method for producing a laminate for electrode pattern production of the present invention, one black layer can be provided in a step after the step of providing an electrode layer without providing the black layer in the step before providing the electrode layer; and a step of modifying the one face in the thickness direction of the transparent substrate is included: therefore, with a simple method with low costs, a laminate for electrode pattern production with decreased reflectance of the underlying metal, and a touch panel substrate with excellent visibility can be produced.

### BRIEF DESCRIPTION OF THE DRAWINGS

FIG. 1A to FIG. 1E are process drawings showing a method for producing an embodiment of a laminate for electrode pattern production and a touch panel substrate of the present invention,

FIG. 1A illustrating a step of preparing a transparent substrate and modifying the back face of the transparent substrate,

FIG. 1B illustrating a step of disposing an underlying metal on the transparent substrate,

FIG. 1C illustrating a step of disposing an electrode layer on the underlying metal,

FIG. 1D illustrating a step of disposing a black layer on the first electrode layer, and

FIG. 1E illustrating a step of patterning the underlying metal, the electrode layer, and the black layer.

FIG. 2 shows a cross-sectional view of a liquid crystal display device including the touch panel substrate shown in FIG. 1E.

FIG. 3A to FIG. 3D are process drawings showing a modification of the method for producing an embodiment of a laminate for electrode pattern production and a touch panel substrate of the present invention,

FIG. 3A illustrating a step of preparing a transparent substrate and modifying the back face of the transparent substrate,

FIG. 3B illustrating a step of disposing an underlying metal on the transparent substrate,

FIG. 3C illustrating a step of disposing an electrode layer on the underlying metal, and

FIG. 3D illustrating a step of patterning the underlying metal and the electrode layer.

FIG. 4 shows a processed SEM image of the second underlying metal of Example 1.

FIG. 5 shows a processed SEM image of the second underlying metal of Example 2.

FIG. 6 shows a processed SEM image of the second underlying metal of Example 4.

FIG. 7 shows a processed SEM image of the second underlying metal of Comparative Example 1.

FIG. 8 shows a processed SEM image of the second underlying metal of Comparative Example 3.

FIG. 9A to FIG. 9C are process drawings showing a method for producing a laminate for transparent electrode pattern production (conventional example),

FIG. 9A illustrating a step of preparing a first transparent substrate on which a first electrode layer and a first black layer are sequentially laminated on the surface thereof,

FIG. 9B illustrating a step of preparing a second transparent substrate on which a second electrode layer and a second black layer are sequentially laminated on the surface thereof, and

FIG. 9C illustrating a step of bonding the first transparent substrate and the second transparent substrate.

FIG. 10A to FIG. 10C are process drawings showing a method of producing a laminate described in Japanese Unexamined Patent Publication No. 2013-129183,

FIG. 10A illustrating a step of forming a second black layer,

FIG. 10B illustrating a step of forming a first conductor layer and a second conductor layer, and

FIG. 10C illustrating a step of forming a first black layer.

### DETAILED DESCRIPTION OF THE INVENTION

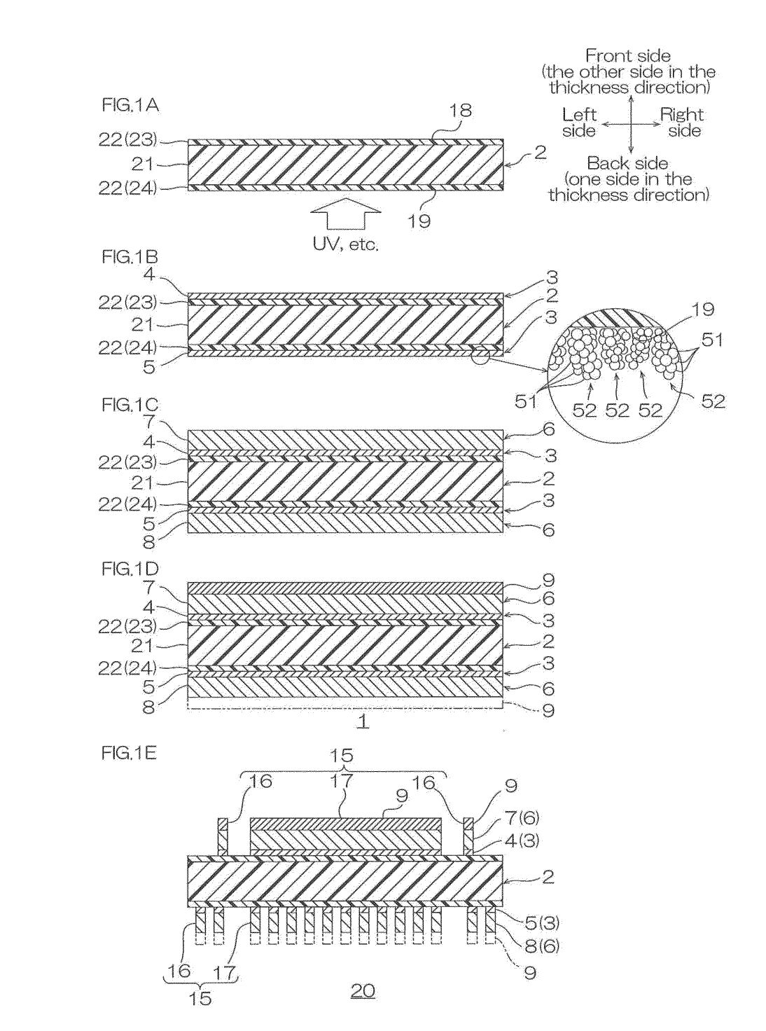

In FIG. 1, up-down directions on the plane of the sheet are front and back directions (thickness direction of the laminate for electrode pattern production, first direction) of the laminate for electrode pattern production (described later); the lower side on the plane of the sheet is a back side (one side in the thickness direction, one side in the first direction); and the upper side on the plane of the sheet is a front side (the other side in the thickness direction, the other side in the first direction). In FIG. 1, the front and back directions are relative to the transparent substrate described later.

In FIG. 1, the left-right directions on the plane of the sheet are left-right directions (width direction, second direction perpendicular to the first direction), left side on the plane of the sheet is a left side (one side in the width direction, one side in the second direction), right side on the plane of the sheet is a right side (the other side in the width direction, the other side in the second direction). In FIG. 1, the sheet thickness direction on the plane of the sheet is front-back directions (third direction perpendicular to the first direction and the second direction), and the near side relative to the plane of the sheet is an anterior side (one side in the third direction), and the far side relative to the plane of the sheet is a posterior side (the other side in the third direction). To be specific, the directions are in conformity with the direction arrows in each figure.

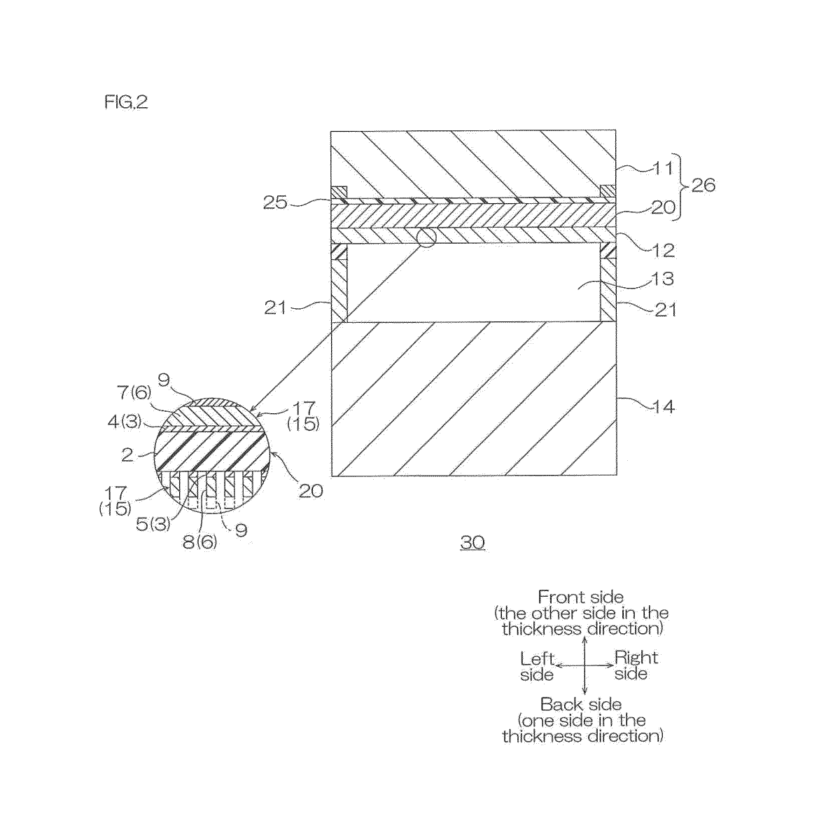

As shown in FIG. 1D, a laminate 1 for electrode pattern production has a plate shape having a predetermined thickness. The laminate 1 extends in a predetermined direction (plane direction, to be specific, left-right directions and front-back directions) perpendicular to the thickness direction. The laminate 1 has a flat front face and a flat back face. The laminate 1 for electrode pattern production is a component for producing, for example, a touch panel substrate 20 (ref: FIG. 1E) included in an image display device such as a liquid crystal display device 30 (ref: FIG. 2) described later. That is, the laminate 1 for electrode pattern production is not an image display device. That is, the laminate 1 for electrode pattern production is a component for producing an image display device. The laminate 1 does not include an image display element such as an LCD module 14 (ref: FIG. 2). The laminate 1 consists of a transparent substrate 2, an underlying metal 3, and an electrode layer 6 described later (ref: FIG. 1D). The laminate 1 is solely distributed as is as a component. The laminate 1 is an industrially applicable device.

To be specific, as shown in FIG. 1D, the laminate 1 for electrode pattern production includes a transparent substrate 2, underlying metals 3 disposed on the front face 18 and the back face 19 of the transparent substrate 2, electrode layers 6 disposed on the front face of the underlying metal 3 at the front side and on the back face of the underlying metal 3 at the back side, and a black layer 9 disposed on the front face of the electrode layer 6 at the front side. Preferably, the laminate 1 for electrode pattern production is composed of the transparent substrate 2, the underlying metal 3, the electrode layer 6, and the black layer 9.

The transparent substrate 2 has a film shape (or a thin-plate shape), and when viewed from the top, the transparent substrate 2 corresponds to the outline shape of the laminate 1 for electrode pattern production. Examples of transparent materials forming the transparent substrate 2 include insulating materials of organic transparent materials and inorganic transparent materials. Examples of the organic transparent material include polyester materials such as polyethylene terephthalate (PET); acrylic materials such as polymethacrylate; polycarbonate materials; olefin materials such as polyethylene (PE), polypropylene (PP), and cycloolefin polymers (COP); and melamine polymers. Examples of the inorganic transparent material include glass. Preferably, in view of its thinness and lightweight, organic transparent materials, more preferably, polyester materials are used.

The transparent substrate 2 can be used singly, or can be used in a combination of two or more. When the transparent substrate 2 has two or more transparent materials in combination, layers of a plurality of different types of transparent materials can also be laminated. To be specific, two types of polyester materials can be laminated in the thickness direction. To be more specific, the transparent substrate 2 can include a substrate layer 21 made of one polyester material (e.g., PET, etc.), and an adhesion primer layer 22 disposed on both of the front and back faces thereof, and composed of other polyester material (a polyester material that is a different type from the one polyester material, for example, a copolymer of dicarboxylic acid such as terephthalic acid and a glycol component such as ethylene glycol, etc.). The adhesion primer layer 22 is a layer provided to improve adhesive strength of the underlying metal 3 described next to the substrate layer 21, and to be specific, includes a first adhesive primer layer 23 disposed on the front face of the substrate layer 21 and a second adhesive primer layer 24 disposed on the back face of the substrate layer 21.

The transparent substrate 2 has a total luminous transmittance of, for example, 80% or more, preferably 90% or more, and for example, 100% or less.

The transparent substrate 2 has a thickness of, in view of light transmission and handling properties, for example, 5 μm or more, preferably 15 μm or more, and, for example, 100 μm or less, preferably 50 μm or less. When the transparent substrate 2 includes the substrate layer 21 and the adhesion primer layer 22, the substrate layer 21 has a thickness of, for example, 5 μm or more, preferably 15 μm or more, and for example, 100 μm or less, preferably 50 μm or less, and each of the adhesion primer layer 22 has a thickness of, for example, 5 nm or more, preferably 20 nm or more, and for example, 1000 nm or less, preferably 100 nm or less.

The underlying metal 3 is disposed on the front face 18 and the back face 19 of the transparent substrate 2 so that the underlying metal 3 is in direct contact with the front face 18 and the back face 19 of the transparent substrate 2. Each of the underlying metals 3 has a thin film shape having the same shape with that of the transparent substrate 2 when viewed from the top. The underlying metal 3 is configured as a seed layer for forming an electrode layer 6 to be described next by, for example, electrolytic plating. The underlying metal 3 includes a first underlying metal 4 (underlying metal 3 of the front side) disposed on the front face 18 of the transparent substrate 2 and a second underlying metal 5 (underlying metal 3 of the back side) disposed on the back face 19 of the transparent substrate 2.

The first underlying metal 4 is formed from primary particles of metal particles 51 to be described later. That is, the first underlying metal 4 is formed from homogeneously dispersed metal particles 51 on the front face 18 of the transparent substrate 2 without agglomeration of the metal particles 51.

Examples of the metals that form the first underlying metal 4 include conductors (low resistance metals) such as copper, nickel, chromium, and alloys thereof, and preferably, copper, a copper alloy (e.g., CuNi having a Ni content of 0.1 to 5 mass % etc.), nickel, and a nickel alloy (NI—P, Ni—B, etc.) are used, more preferably, copper and nickel are used. The metals can be used singly, or can be used in a combination of two or more.

The surface resistance of the first underlying metal 4 is set suitably in accordance with the metals that produce the electrode layer 6, and when producing the electrode layer 6 by electrolytic plating, the first underlying metal 4 has a surface resistance of, for example, 5Ω/□ or less, preferably 3Ω/□ or less, more preferably 1Ω/□ or less, and in view of plating time and production costs, for example, 0.01Ω/□ or more, preferably 0.1Ω/□ or more.

The first underlying metal 4 has an average particle size (primary particle size) of, for example, 10 nm or more, and for example, 30 nm or less. The average particle size of the metal particles 51 is calculated, for example, by processing of SEM image of the underlying metal 3.

The first underlying metal 4 has a thickness of, for example, 10 nm or more, preferably 50 nm or more, and for example, 1000 nm or less, preferably 500 nm or less.

The front face of the first underlying metal 4 has an arithmetical roughness Ra of, for example, 10 nm or more, and for example, 50 nm or less. The arithmetical roughness Ra of the front face of the first underlying metal 4 is calculated in conformity with JIS B 0601.

The second underlying metal 5 is formed from metal particles, as shown in the right side figure of FIG. 1B. To be specific, the second underlying metal 5 includes agglomerated particles 52 which are agglomerated primary particles of the metal particles 51.

The agglomerated particles 52 are formed into a shape like a bunch of grapes, in which primary particles of the plurality of metal particles 51 are agglomerated. The metal particles 51 are formed substantially spherical or bulky.

In the second underlying metal 5, the above-described plurality of agglomerated particles 52 are disposed on the back face 19 of the transparent substrate 2 cohesively and densely. That is, the plurality of agglomerated particles 52 are disposed so as to cover substantially the entire back face 19 of the transparent substrate 2.

Examples of the metals that form the second underlying metal 5 include those metals given as examples of the metals forming the first underlying metal 4.

The back face resistance of the second underlying metal 5 is suitably set with the metal that produces the second electrode layer 8 when the second electrode layer 8 is produced by electrolytic plating, and for example, the second underlying metal 5 has a back face resistance of 5Ω/□ or less, preferably 3Ω/□ or less, more preferably 1Ω/□ or less, and in view of plating time and production costs, for example, 0.01Ω/□ or more, preferably 0.1Ω/□ or more.

The size of the second underlying metal 5 is suitably adjusted in order to set the back face resistance of the second underlying metal 5 in the above-described range. To be specific, the thickness of the second underlying metal 5 is the same as the average particle size of the agglomerated particles 52 to be described next.

The agglomerated particles 52 have an average particle size (secondary particle size) of, for example, 30.0 nm or more, preferably 40.0 nm or more, more preferably 50.0 nm or more, and for example, 300 nm or less, preferably 200 nm or less, more preferably 100 nm or less. The average particle size of the agglomerated particles 52 is calculated by the method described in Examples later on.

When the agglomerated particles 52 have an average particle size (secondary particle size) of the above-described lower limit or more, reflectance (described later) of the front face of the second underlying metal 5 can be set to the desired range, and therefore decrease in visibility from the front side of the second underlying metal 5 can be prevented. That is, decrease in visibility from the viewer side (front side in FIG. 2, described later) in the liquid crystal display device 30 (ref: FIG. 2) can be prevented.

The metal particles 51 have an average particle size (primary particle size) of, for example, 10 nm or more, and for example, 30 nm or less.

The arithmetical roughness Ra of the back face of the second underlying metal 5 is adjusted by the secondary particle size of the above-described agglomerated particles 52, to be specific, 100 nm or more, preferably 150 nm or more, more preferably 200 nm or more, and, for example, 1000 nm or less, preferably 500 nm or less. The arithmetical roughness Ra of the back face of the second underlying metal 5 is calculated in conformity with JIS B 0601.

When the arithmetical roughness Ra of the back face of the second underlying metal 5 is less than the above-described lower limit, reflectance of the front face of the second underlying metal 5 cannot be set to low, and therefore decrease in visibility from the front side of the second underlying metal 5, that is, decrease in visibility from the viewer side (front side in FIG. 2, described later) of the liquid crystal display device 30 (ref: FIG. 2) cannot be prevented. When the arithmetical roughness Ra of the back face of the second underlying metal 5 is the above-described upper limit or less, the arithmetical roughness Ra of the back face of the second underlying metal 5 can be set in the desired range, reflectance (described later) of the front face of the second underlying metal 5 can be set within the desired range, and therefore decrease in visibility from the front side of the second underlying metal 5 can be prevented.

The reflectance of the front face of the second underlying metal 5 is, for example, 20.0% or less, preferably 15.0% or less, more preferably 10.0% or less, and for example, 0.0% or more, preferably 0.1% or more. The reflectance of the front face of the second underlying metal 5 is defined as luminous reflectance value Y measured by using a spectrophotometer. To be specific, the method for calculating the reflectance of the front face of the second underlying metal 5 is described in detail in Examples later on.

When the reflectance of the front face of the second underlying metal 5 is the above-described upper limit or less, decrease in visibility from the front side of the second underlying metal 5, that is, decrease in visibility from the viewer side of the liquid crystal display device 30 (ref: FIG. 2) (front side in FIG. 2, described later) can be prevented.

The electrode layers 6 are disposed so as to directly contact the front face of the underlying metal 3 of the front side and the back face of the underlying metal 3 of the back side. Each of the electrode layers 6 has a film shape (or a thin-plate shape) having the same shape as that of the transparent substrate 2 when viewed from the top. To be specific, the electrode layers 6 include a first electrode layer 7 disposed on the front face of the first underlying metal 4 and a second electrode layer 8 disposed on the back face of the second underlying metal 5.

The first electrode layer 7 has a film shape having a shape that corresponds to the outline shape of the transparent substrate 2. Examples of materials that form the first electrode layer 7 include gold, silver, copper, nickel, aluminum, magnesium, tungsten, cobalt, zinc, iron, and alloys thereof, and preferably, gold, silver, and copper are used, more preferably in view of costs and workability/processability, copper is used.

The thickness of the first electrode layer 7 is set suitably in accordance with the resistance required by the touch panel substrate 20 (described later, ref: FIG. 1E), to be specific, for example, 10 nm or more, preferably 100 nm or more, and for example, 20 μm or less, preferably 10 μm or less, more preferably 5 μm or less.

Examples of materials that form the second electrode layer 8 and the thickness of the second electrode layer 8 are the same as those for the above-described first electrode layer 7.

The above-described electrode layer 6 can integrally compose, with the above-described underlying metal 3 and the black layer 9 to be described next, an electrode pattern 15 (ref: FIG. 1E) described later.

The black layer 9 is disposed on the entire front face of the first electrode layer 7. The black layer 9 has a film shape having an outline shape that corresponds to the outline shape of the first electrode layer 7. The black layer 9 is provided to suppress metallic luster on the front face of the first electrode layer 7, and to prevent decrease in visibility from the viewer side of the first electrode layer 7 (front side in FIG. 2, described later) when the touch panel substrate 20 produced with the laminate 1 for electrode pattern production is included in a liquid crystal display device 30 (ref: FIG. 2).

Examples of materials that form the black layer 9 include metal materials such as copper nitride, copper oxide, nickel nitride, nickel oxide, nickel zinc (NiZn), nickel tin, and tin zinc, or a resin composition black pigment. Preferably, metal materials, more preferably, nickel zinc (NiZn) is used. Those materials can be used singly, or can be used in a combination of two or more. The black layer 9 has a thickness of, for example, 5 nm or more, preferably 10 nm or more, and for example, 200 μm or less, preferably 1 μm or less. The black layer 9 has a reflectance of, for example, 20% or less, preferably 10% or less, and for example, 1% or more.

The above-described laminate 1 for electrode pattern production include a black layer 9, a first electrode layer 7, a first underlying metal 4, a transparent substrate 2, a second underlying metal 5, and a second electrode layer 8 in sequence from the front side (the other side in the thickness direction) to the back side (one side in the thickness direction).

(Method for Producing a Laminate for Electrode Pattern Production)

Next, description is given below of a method for producing the laminate 1 for electrode pattern production.

The method for producing the laminate 1 for electrode pattern production include preparing a transparent substrate 2 (ref: FIG. 1A), modifying the transparent substrate 2 (ref: arrow in FIG. 1A), disposing the underlying metal 3 on the front face 18 and the back face 19 of the transparent substrate 2 (ref: FIG. 1B), disposing the electrode layer 6 on the front face and the back face of the underlying metal 3 (ref: FIG. 1C), and disposing the black layer 9 on the front face of the first electrode layer 7 (ref: FIG. 1D).

Each of the steps is described below.

(Preparation Step)

As shown in FIG. 1A, in the step of preparing the transparent substrate 2, the transparent substrate 2 having the above-described configuration, materials, and size is prepared.

(Modifying Step)

As shown with the arrow in FIG. 1A, the modifying step is performed after the preparation step.

In the modifying step, for example, the back face 19 of the transparent substrate 2 is modified (when the transparent substrate 2 includes a substrate layer 21, a first adhesion primer layer 23, and a second adhesion primer layer 24, the back face 19 of the second adhesion primer layer 24 is modified).

Modifying of the transparent substrate 2 is a treatment in which origination points for generating agglomerated particles 52 to be described later are given on the back face 19 of the transparent substrate 2 (second adhesion primer layer 24).

The back face 19 of the transparent substrate 2 is modified by, for example, active energy rays, plasma, or laser. The modification of the transparent substrate 2 can be performed singly, or two or more modifications can be performed in sequence.

When the transparent substrate 2 is modified by one selected from the group consisting of active energy rays, plasma, and laser, the origination points for generating the agglomerated particles 52 to be described later can be formed reliably on the back face 19 of the transparent substrate 2.

Preferably, the back face 19 of the transparent substrate 2 is irradiated (exposed) with active energy rays.

Examples of the active energy rays include ultraviolet rays, radial rays, infrared rays, X-rays, α-rays, β-rays, γ-rays, and electron beam. Preferably, ultraviolet rays are used.

When using ultraviolet rays as the active energy rays, ultraviolet rays can be generated, for example, by a low pressure mercury lamp, high pressure mercury lamp, ultra high pressure mercury lamp, metal halide lamp, electrodeless lamp (fusion lamp), chemical lamp, black light lamp, mercury-xenon lamp, short arc lamp, helium.cadmium laser, argon laser, sunlight, and LED. Preferably, a low pressure mercury lamp is used.

The irradiation amount (exposure amount) of the active energy rays is set suitably in accordance with the materials of the transparent substrate 2, conditions for pretreatment performed as necessary thereafter, and materials of the electrode layer 6, and for example, 200 mW/cm² or more, preferably 500 mW/cm² or more, more preferably 1000 mW/cm² or more, and for example, 10000 mW/cm² or less, preferably 5000 mW/cm² or less, more preferably 2000 mW/cm² or less. When the irradiation amount of the active energy ray is the above-described lower limit or more, generation of the agglomerated particles 52 to be described next can be sufficiently accelerated. Thus, a desired reflectance can be obtained. When the irradiation amount of the active energy ray is the above-described upper limit or less, effects of accelerating production of the agglomerated particles 52 adequate for the irradiation amount can be obtained, and therefore increase in production costs can be suppressed.

The irradiation time of the active energy ray is suitably set so as to achieve the above-described irradiation amount, and for example, 1 second or more, preferably 10 seconds or more, and for example, 20 minutes or less, preferably 10 minutes or less.

The output in the ultraviolet ray generation is different depending on variety of products. The output is 40 W or more, preferably 200 W or more, and for example, 1000 W or less, preferably 500 W or less.

The time for modifying the transparent substrate 2 is, for example, 1 second or more, preferably 10 seconds or more, and for example, 600 seconds or less, preferably 60 seconds or less.

(Underlying Metal Disposing Step)

As shown in FIG. 1B, the underlying metal disposing step is performed after the modifying step.

In the underlying metal disposing step, the underlying metal 3 is disposed on the front face 18 and the back face 19 of the transparent substrate 2.

In the disposing on the front face 18 and the back face 19 of the transparent substrate 2, for example, electroless plating and sputtering are used, and preferably, in view of production costs, electroless plating is used. In electroless plating, the agglomerated particles 52 can be reliably produced on the transparent substrate 2 with its back face 19 modified, and therefore a desired reflectance can be produced.

To be specific, the transparent substrate 2 with its back face 19 modified is immersed in an electroless plating solution.

In electroless plating, a pretreatment can also be performed before immersing the transparent substrate 2 in the electroless plating solution.

The pretreatment is a known treatment for performing electroless plating on the transparent substrate 2, and examples thereof include a washing treatment, catalyst treatment, and activation treatment.

The washing treatment include degreasing treatment in which oil (fat) attached to the front face 18 and the back face 19 of the transparent substrate 2 is removed.

The catalyst treatment is a treatment in which, for example, a catalyst coating containing a catalyst such as palladium is attached to the front face 18 and the back face 19 of the transparent substrate 2.

The activation treatment is a treatment for preventing uneven plating by stably reductively depositing the catalyst (to be specific, Pd, etc.) attached by the catalyst treatment.

The conditions for the pretreatment are set suitably.

After the pretreatment, the transparent substrate 2 is immersed in an electroless plating solution.

The electroless plating solution contains, for example, metal (or metal ion) that forms the underlying metal 3.

The immersion time is not particularly limited, as long as the time allows for production of the agglomerated particles 52. The immersion time is 10 seconds or more, preferably 30 seconds or more, and for example, 10 minutes or less, preferably 5 minutes or less.

In this manner, the first underlying metal 4 is disposed on the front face 18 of the transparent substrate 2, and the second underlying metal 5 is disposed on the back face 19 of the transparent substrate 2.

Then, in this underlying metal disposing step, as shown in the enlarged view encircled on the right side in FIG. 1B, the back face 19 of the transparent substrate 2 is modified in the above-described modifying step, and therefore the metal particles 51 agglomerate like a bunch of grapes, thereby forming a plurality of the agglomerated particles 52 having a desired secondary particle size. In this manner, the second underlying metal 5 with a back face having an arithmetical roughness Ra of a specific value or more is formed. That is, the plurality of agglomerated particles 52 form unevenness on the back face of the second underlying metal 5.

(Electrode Layer Disposing Step)

As shown in FIG. 1C, the electrode layer disposing step is performed after the underlying metal disposing step.

In the electrode layer disposing step, the electrode layer 6 is disposed on the exposed face of the underlying metal 3. To be specific, the first electrode layer 7 is disposed on the front face (that is, the face that is opposite to the face that is in contact with the transparent substrate 2 in the first underlying metal 4) of the first underlying metal 4, and the second electrode layer 8 is disposed on the back face of the second underlying metal 5 (the face that is opposite to the face that is in contact with the transparent substrate 2 in the second underlying metal 5).

The electrode layer 6 can be disposed on the exposed surface of the underlying metal 3 by, for example, electrolytic plating, or sputtering, and in view of production costs, preferably, electrolytic plating is used. With electrolytic plating, the electrode layer 6 having a desired thickness can be formed reliably.

To be specific, the transparent substrate 2 provided with the underlying metal 3 is, for example, immersed in an electrolytic plating solution. Furthermore, before the above-described immersion, a power supply member (not shown) is brought into contact with the electrode layer 6 in advance.

The conditions for electrolytic plating, to be specific, the temperature of the electrolytic plating solution, and the ion concentration and the electric current density of the electrolytic plating solution are set suitably.

(Black Layer Disposing Step)

As shown in FIG. 1D, the black layer disposing step is performed after the electrode layer disposing step.

In the black layer disposing step, the black layer 9 is disposed on the front face of the first electrode layer 7.

For example, when the black layer 9 is formed from a metal material, for example, the black layer 9 is laminated on the front face of the first electrode layer 7 by plating.

In this manner, the laminate 1 for electrode pattern production is produced.

Then, the laminate 1 for electrode pattern production shown in FIG. 1D is distributed as a component for producing the touch panel substrate 20 shown in FIG. 1E, and is an industrially applicable device (component).

### <Touch Panel Substrate>

Thereafter, as shown in FIG. 1E, the touch panel substrate 20 in which the electrode pattern 15 is formed is produced by patterning the underlying metal 3, electrode layer 6, and black layer 9 in the laminate 1 for electrode pattern production.

As shown in FIG. 1E, the touch panel substrate 20 includes the transparent substrate 2, and the electrode pattern 15 disposed on the front face and the back face of the transparent substrate 2. Preferably, the touch panel substrate 20 consists of the transparent substrate 2 and the electrode pattern 15.

The electrode pattern 15 on the front side of the transparent substrate 2 includes the first underlying metal 4, first electrode layer 7, and black layer 9, and on the back side of the transparent substrate 2, includes the second underlying metal 5 and second electrode layer 8. The electrode pattern 15 includes a lead wire 16 and an electrode 17 formed continuously with the lead wire 16 (although not shown).

The lead wire 16 is disposed in a plural number at the peripheral end portion of the touch panel substrate 20 in spaced-apart relation to each other.

The electrode 17 composes a detection portion (sensor) in the liquid crystal display device 30 (ref: FIG. 2) described later, and is disposed in a plural number at the center of the touch panel substrate 20 in spaced-apart relation to each other. The pattern of the electrode 17 is formed into a lattice when projected in the thickness direction. To be specific, the electrode 17 disposed on the front side of the transparent substrate 2 and the electrode 17 disposed on the back side of the transparent substrate 2 are formed to cross each other at right angles, for example, when projected in the thickness direction. To be specific, the electrodes 17 disposed on the front side of the transparent substrate 2 extend in left-right directions, and are formed in spaced-apart relation to each other in front-back directions. Meanwhile, the electrodes 17 disposed on the back side of the transparent substrate 2 extend in front-back directions, and are formed in spaced-apart relation to each other left-right directions.

As shown in FIG. 1E, for patterning of the first underlying metal 4, the first electrode layer 7, and the black layer 9 which are disposed on the front side of the transparent substrate 2, and also the second underlying metal 5 and the second electrode layer 8 which are disposed on the back side of the transparent substrate 2 into the electrode pattern 15, for example, they are subjected to etching.

As shown in FIG. 1E, the touch panel substrate 20, in which the electrode pattern 15 including the lead wire 16 and the electrode 17 is formed on both of the front face and the back face of the transparent substrate 2 is produced in this manner.

### <Touch Panel and Liquid Crystal Display Device>

Next, description is given below of the liquid crystal display device 30 including the touch panel substrate 20 shown in FIG. 1E, with reference to FIG. 2.

In FIG. 2, the liquid crystal display device 30 is, for example, a touch panel mobile phone, which is viewed and operated by an operator (or a viewer) from the front side. The liquid crystal display device 30 includes, as a platy image display element, an LCD module (liquid crystal display module) 14, a polarizing plate 12 provided on the front side of the LCD module 14 in spaced-apart relation, and a touch panel 26 disposed on the front face of the polarizing plate 12.

Although not shown, for example, a circuit board and a housing are provided on the back side of the LCD module 14.

A gap layer 13 as an air layer is provided between the LCD module 14 and the polarizing plate 12 at the center portion of the left-right directions and the front-back directions of the liquid crystal display device 30. The gap layer 13 is defined by the spacer 21 disposed like a frame at the peripheral end portion.

The touch panel 26 includes a touch panel substrate 20 disposed on the front face of the polarizing plate 12, and a protection glass layer 11 that is allowed to adhere to the front side of the touch panel substrate 20 with a transparent pressure-sensitive adhesive layer 25 interposed therebetween.

In the touch panel 26 in FIG. 2, the touch panel substrate 20 shown in FIG. 1E is disposed in the liquid crystal display device 30 while keeping the arrangement in the front and back directions.

That is, as shown in the enlarged view encircled on the left side in FIG. 2, the touch panel substrate 20 in the touch panel 26 of the liquid crystal display device 30, the first underlying metal 4, the first electrode layer 7, and the black layer 9 are disposed on the front side of the transparent substrate 2. That is, the first underlying metal 4, the first electrode layer 7, and the black layer 9 are disposed in this sequence from the transparent substrate 2 toward the front side.

Meanwhile, the second underlying metal 5 and the second electrode layer 8 are disposed on the back side of the transparent substrate 2. That is, the second underlying metal 5 and the second electrode layer 8 are disposed in this sequence from the transparent substrate 2 toward the back side.

That is, in the touch panel substrate 20 of the liquid crystal display device 30, the black layer 9, first electrode layer 7, first underlying metal 4, transparent substrate 2, second underlying metal 5, and second electrode layer 8 are disposed in sequence from the front side (the other side in the thickness direction) toward the back side (one side in the thickness direction).

In the liquid crystal display device 30, when fingers are brought into contact or near contact with the front face of the protection glass layer 11 corresponding to the electrode 17, compared with the case where fingers are not brought into contact or near contact, a capacitance difference is caused, and the capacitance difference is transmitted to a circuit board (not shown) as detection signals through the lead wire 16.

Meanwhile, input signals are entered from the circuit board to the LCD module 14. The input signals cause the LCD module 14 to display images. The images are viewed by an operator (or a viewer) through the polarizing plate 12 and the touch panel 26.

On the other hand, decrease in image visibility as described above may be caused when a viewer sees the image displayed on the LCD module 14, when natural light entered from the front side penetrates the protection glass layer 11 and adhesive layer 25, and then penetrates between the plurality of electrode patterns 15 composed of the black layer 9, first electrode layer 7, and first underlying metal 4, and then reflected (or metallic luster) at the front face of the electrode pattern 15 disposed at the back side of the transparent substrate 2, to be specific, at the front face of the second underlying metal 5 (viewer side face) after penetrating the transparent substrate 2. However, according to this embodiment, because the agglomerated particles 52 are formed so that the arithmetical roughness Ra of the back face of the second underlying metal 5 is the above-described lower limit or more, metallic luster caused at the front face of the second underlying metal 5 is suppressed, that is, reflection of natural light at the front face of the second underlying metal 5 in the liquid crystal display device 30 can be suppressed.

Decrease in visibility caused by metallic luster at the front face of the electrode pattern 15 disposed on the front side of the transparent substrate 2, to be specific, at the front face of the first electrode layer 7 is suppressed by the black layer 9.

(Operations and Effects of this Embodiment)

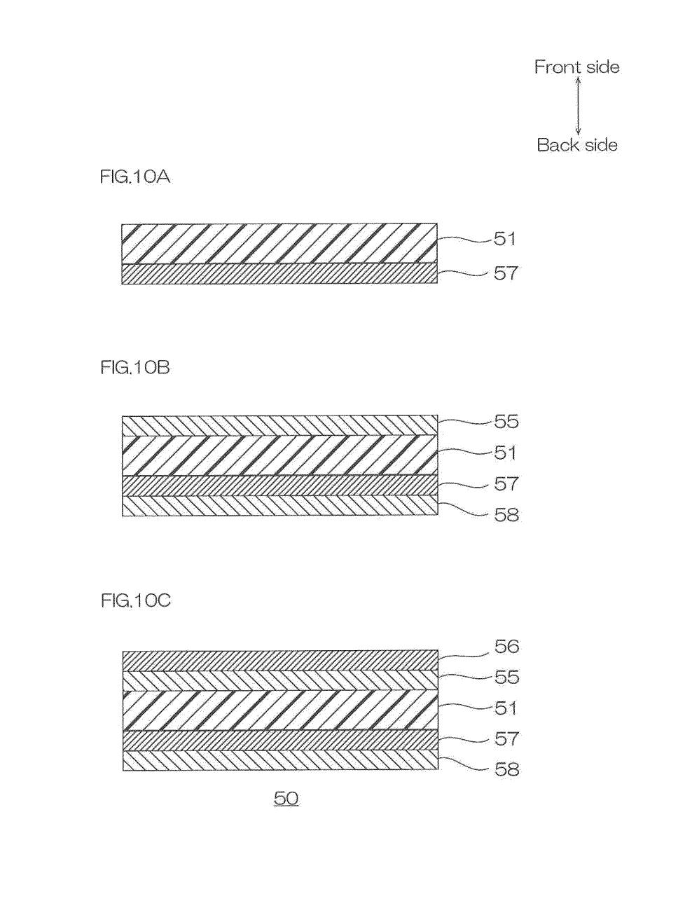

Then, in the laminate 1 for electrode pattern production and the touch panel substrate 20, without providing the black layer 9 on the back face 19 of the transparent substrate 2, that is, as shown in FIG. 10A to FIG. 10C, without providing the second black layer 57 and the first black layer 56 in separate steps (step of FIG. 10A and step of FIG. 10C), that is, without providing the black layer 9 in the step before the electrode layer disposing step (ref: FIG. 1C), the reflectance of the front face of the second underlying metal 5 shown in FIG. 1D and FIG. 1E can be set to low by just a simple configuration in which one black layer 9 is provided in the black layer disposing step after the electrode layer disposing step (ref: FIG. 1C) (ref: FIG. 1C), and then setting the arithmetical roughness Ra of the back face of the second underlying metal 5 for providing the second electrode layer 8 to a specific lower limit or more.

Thus, the liquid crystal display device 30 shown in FIG. 2 and including the touch panel substrate 20 made from the laminate 1 for electrode pattern production allows for prevention of decrease in visibility from the front side (viewer side, ref: FIG. 2.) caused by metallic luster of the second underlying metal 5 in LCD module 14, and a simple configuration of the touch panel substrate 20.

Furthermore, in the production method of the laminate 1 for electrode pattern production and the touch panel substrate 20 shown in FIG. 1A to FIG. 1E, without providing the second black layer 57 and the first black layer 56 as shown in FIG. 10A to FIG. 10C in separate steps (step in FIG. 10A and step in FIG. 10C), that is, the black layer 9 is not provided in the step before the electrode layer disposing step (ref: FIG. 1C), and providing one black layer 9 (ref: FIG. 1D) in the black layer disposing step after the electrode layer disposing step (ref: FIG. 1C), and including the step of modifying the transparent substrate 2 (step of FIG. 1A), the reflectance of the front face of the second underlying metal 5 is set to low, and the laminate 1 for electrode pattern production, and a touch panel substrate 20 having excellent visibility can be produced with low costs and a simple method. To be specific, in the conventional method of Japanese Unexamined Patent Publication No. 2013-129183, as shown in FIG. 10A and FIG. 10C, the first black layer 56 and the second black layer 57 have to be subjected to vacuum processes that require expensive equipment such as sputtering and plating are necessary in each of the two steps. However, in this embodiment, as shown in FIG. 1D, in the above-described process, one black layer 9 is formed in only one step, and the back face 19 of the transparent substrate 2 is modified by one selected from the group consisting of the active energy rays, plasma, and laser, and therefore the laminate 1 for electrode pattern production and the touch panel substrate 20 can be produced at low costs.

### Modified Embodiments

In the embodiment shown with the solid line in FIG. 1D and FIG. 1E, the black layer 9 is disposed only on the front face of the first electrode layer 7. However, for example, as shown with the phantom line in FIG. 1D and FIG. 1E, the black layer 9 can be disposed further on the back face of the second electrode layer 8. That is, the black layer 9 is disposed on the front face of the first electrode layer 7 and the back face of the second electrode layer 8. In such a case, two black layers 9 are formed simultaneously in one step, for example, by plating, to be specific, only by immersing the transparent substrate 2 provided with the first electrode layer 7 and the second electrode layer 8 in a plating bath.

In the embodiment shown in the solid line shown in FIG. 1D and FIG. 1E, the black layer 9 is disposed separately as a layer apart from the first electrode layer 7. However, for example, as long as metallic luster at the front face of the first electrode layer 7 can be suppressed, and the reflectance of the front face of the first electrode layer 7 can be set to low, without particular limitation, to be specific, without separately providing the black layer 9, fine unevenness can be formed on the front face of the first electrode layer 7 by, for example, etching.

In the embodiment shown in the arrow in FIG. 1A, in the modifying step, only the back face 19 of the transparent substrate 2 is modified. However, for example, although not shown, the front face 18 of the transparent substrate 2 can further be modified.

In such a case, the front face 18 of the first underlying metal 4 has a reflectance that is in the same range as the reflectance of the back face 19 of the second underlying metal 5. That is, the first underlying metal 4 is formed from the agglomerated particles 52 in which primary particles of the plurality of metal particles 51 are agglomerated like a bunch of grapes, and in this manner, the arithmetical roughness Ra of the front face of the first underlying metal 4 has the same range as that of the second underlying metal 5.

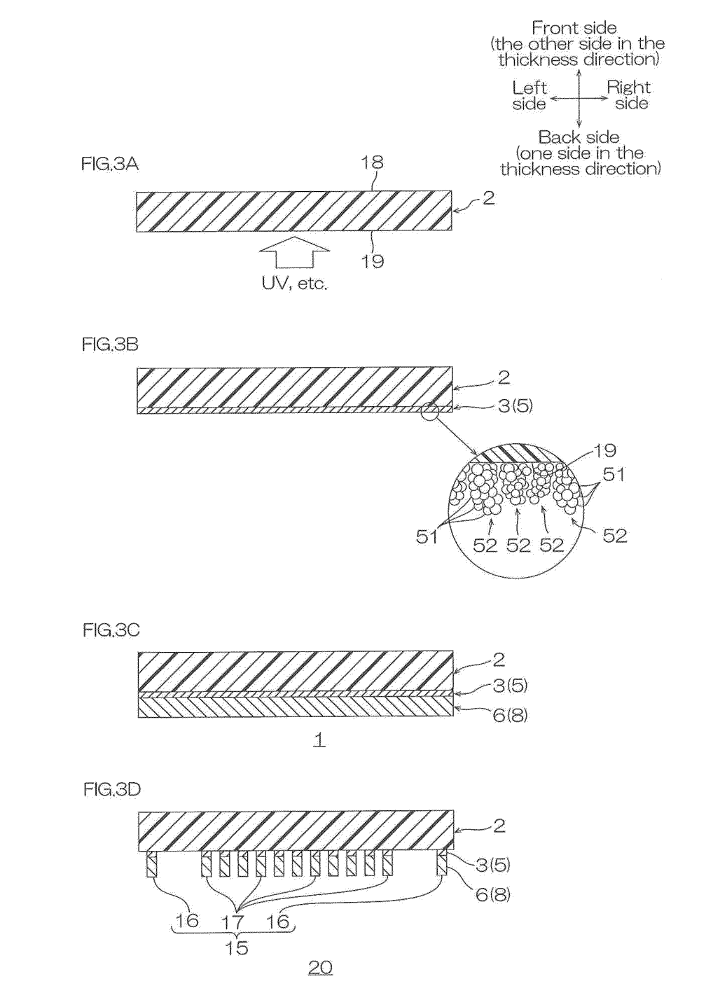

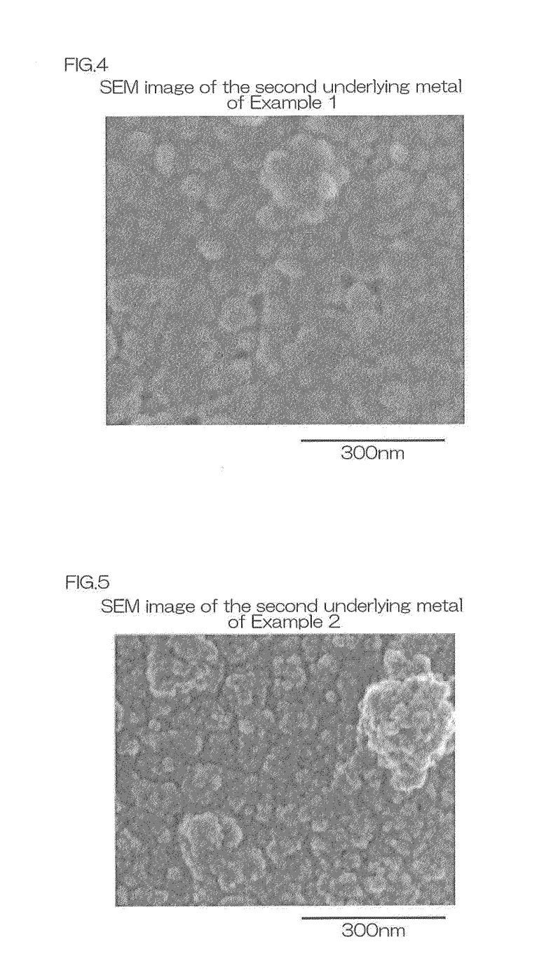

In the embodiment shown in FIG. 1D and FIG. 1E, the underlying metal 3 and the electrode layer 6 are provided on both sides of the transparent substrate 2. That is, the second underlying metal 5 and the second electrode layer 8 are provided on the back side of the transparent substrate 2, and the first underlying metal 4 and the first electrode layer 7 are provided on the front side of the transparent substrate 2. However, for example, as shown in FIG. 3C and FIG. 3D, in the laminate 1 for electrode pattern production, the second underlying metal 5 and the second electrode layer 8 can be provided only on the back side of the transparent substrate 2.

That is, as shown in FIG. 3C, the second underlying metal 5 and the second electrode layer 8 are provided on the back side of the transparent substrate 2, whereas on the front side of the transparent substrate 2, the first underlying metal 4 and the first electrode layer 7 are not provided, and furthermore, no black layer 9 is provided as well. The front face 18 of the transparent substrate 2 is exposed on the front side.

To produce such a laminate 1 for electrode pattern production, first, as shown in FIG. 3A, the transparent substrate 2 is prepared (preparation step), and then, as shown with the arrow in FIG. 3A, the back face 19 of the transparent substrate 2 is modified (modifying step), and then, as shown in FIG. 3B, the underlying metal 3 (second underlying metal 5) is disposed only on the back face 19 of the transparent substrate 2 (underlying metal disposing step), and thereafter, as shown in FIG. 3C, the electrode layer 6 (second electrode layer 8) is disposed on the back face of the underlying metal 3 (second underlying metal 5) (electrode layer disposing step). The laminate 1 for electrode pattern production is produced in this manner.

By patterning the underlying metal 3 and the electrode layer 6 of the laminate 1 for electrode pattern production, as shown in FIG. 3D, a touch panel substrate 20 in which the electrode pattern 15 is formed is formed, and at the time of providing the touch panel 26 of the liquid crystal display device 30 as well, the touch panel substrate 20 is disposed on the liquid crystal display device 30 while keeping the arrangement in the front and back directions.

With this configuration as well, generation of metallic luster on the front face of the second underlying metal 5 is suppressed, that is, reflection of natural light at the front face of the second underlying metal 5 in the liquid crystal display device 30 can be suppressed.

With such a configuration of this modification, as shown in FIG. 3B, there is no need to provide the first underlying metal 4 on the front face 18 of the transparent substrate 2, and therefore the configuration of the laminate 1 for electrode pattern production can be made simple. Furthermore, as shown in FIG. 3C, there is no need to provide the black layer 9 as well, and therefore the laminate 1 for electrode pattern production can be produced with a simple method, and the configuration of the laminate 1 for electrode pattern production can be simplified furthermore.

Preferably, as shown in FIG. 1D and FIG. 1E, the underlying metal 3 is provided on both sides of the transparent substrate 2. With such a configuration, the electrode 17 including the two types of the electrode layers 6 having different arrangements and disposed on both sides of the transparent substrate 2 allows for accurate detection of the position and movement in left-right directions and front-back directions of the finger of the operator at the front face of the protection glass layer 11. Meanwhile, the black layer 9 on the front side of the first electrode layer 7, and the second underlying metal 5 having a specific arithmetical roughness Ra at the front face allow for suppression of metallic luster at the front face of the first electrode layer 7, and decrease in visibility at the front side (viewer side) of the liquid crystal display device 30 caused by metallic luster at the back face of the second underlying metal 5.

In the embodiment shown in FIG. 2, the LCD module 14 is given as an example of the image display element. However, it is not limited thereto, and for example, a CRT, inorganic EL display, organic EL display, LED display, LD display, field emission display, and plasma display can also given as examples.

### EXAMPLES

In the following, the present invention is described in more detail with reference to Examples and Comparative Examples. However, the present invention is not limited to Examples and Comparative Examples.

The numeral values in Examples shown below can be replaced with the numeral values shown in the above-described embodiment (that is, upper limit value or lower limit value).

### Example 1

A transparent substrate (trade name “U48”, manufactured by Toray Industries, Inc.) was prepared: in the transparent substrate, polyester resin layers (thickness 70 nm) as an adhesion primer layer (first adhesion primer layer and second adhesion primer layer) were disposed on both of the front and back faces of a PET film having a thickness of 50 μm as a substrate layer (ref: FIG. 1A).

Then, the back face of the transparent substrate was irradiated with ultraviolet rays for 60 seconds in an irradiation amount of 1260 mJ/cm², with a low pressure mercury lamp (output: 400 W, manufactured by Orc manufacturing Co., Ltd.) (ref: arrow in FIG. 1A). The irradiation amount (exposure) of the ultraviolet ray of the transparent substrate was measured by an ultraviolet ray irradiance meter (UV-351, manufactured by Orc manufacturing Co., Ltd.) disposed near the transparent substrate. The irradiation amount hereinafter was also measured in the same manner. In this manner, the back face of the transparent substrate was modified.

Then, on both of the front and back faces of the transparent substrate, a pretreatment, electroless plating, and electrolytic plating were performed sequentially.

To be specific, in the pretreatment, a washing treatment, catalyst treatment, and activation treatment were performed sequentially.

First, in the washing treatment, the transparent substrate having the back face irradiated with ultraviolet rays was immersed in a conditioner liquid at 70° C. for 3 minutes.

Then, in the catalyst treatment, the washed transparent substrate was immersed in a Pd catalyst solution of 65° C. for 5 minutes. In this manner, the Pd catalyst coating was formed on the front face and the back face of the transparent substrate.

Thereafter, in the activation treatment, the transparent substrate was immersed in 50 g/l of an aqueous hypophosphorous acid solution for 1 minute. In this manner, both of the front and back faces (exposed face of the catalyst coating provided) of the transparent substrate were subjected to an activation treatment.

In this manner, both of the front and back faces of the transparent substrate were pretreated.

Then, the pretreated transparent substrate was immersed in an electroless copper plating solution of 27° C. for 5 minutes. In this manner, on both of the front and back faces of the transparent substrate, an underlying metal (first underlying metal and second underlying metal) made of copper was formed (ref: FIG. 1B). The surface resistance of the first underlying metal and the back face resistance of the second underlying metal was 0.6Ω/□. The surface resistance and the back face resistance were measured with a resistivity meter (Loresta EP MCP-360, manufactured by Mitsubishi Chemical Analytech Co., Ltd.). The surface resistance and the back face resistance mentioned below were measured as described above as well.

Then, the transparent substrate wherein the underlying metals (first underlying metal and second underlying metal) were formed on both of the front and back faces was immersed in a copper sulfate plating solution of 23° C., and electrolytic plating was performed with an average electric current density of 0.5 A/dm² for 2 minutes. In this manner, electrode layers (first electrode layer and second electrode layer) made of copper and having a thickness of 200 nm were formed on the front face of the first underlying metal, and the back face of the second underlying metal (ref: FIG. 1C). The surface resistance of the first electrode layer and the back face resistance of the second electrode layer were 0.1 Ω/□.

Thereafter, the transparent substrate on which the electrode layers (the first electrode layer and the second electrode layer) were formed on both of the front and back sides was immersed in a NiZn plating solution of 30° C., and electrolytic plating was performed with an average electric current density of 0.08 A/dm² for 90 seconds (ref: phantom line in FIG. 1D). In this manner, the black layers made of NiZn and having a thickness of 50 nm were formed on the front face of the first electrode layer, and on the back face of the second electrode layer.

### Example 2

A transparent substrate (trade name “U48”, manufactured by Toray Industries, Inc.) was prepared: in the transparent substrate, polyester resin layers (thickness 70 nm) as an adhesion primer layer were disposed on both of the front and back faces of a PET film having a thickness of 50 μm (ref: FIG. 1A).

Then, the back face of the transparent substrate was irradiated with ultraviolet rays for 60 seconds in an irradiation amount of 1245 mJ/cm², with a low pressure mercury lamp (output: 400 W, manufactured by Orc manufacturing Co., Ltd.) (ref: arrow in FIG. 1A). In this manner, the back face of the transparent substrate was modified.

Then, on both of the front and back faces of the transparent substrate, a pretreatment, electroless plating, and electrolytic plating were performed sequentially.

To be specific, in the pretreatment, a washing treatment, a catalyst treatment, and an activation treatment were performed sequentially.

First, in the washing treatment, the transparent substrate having the back face irradiated with ultraviolet rays was immersed in a conditioner liquid of 70° C. for 3 minutes. In this manner, both of the front and back faces of the transparent substrate was washed (degreasing treatment).

Then, in the catalyst treatment, the washed transparent substrate was immersed in a Pd catalyst solution of 30° C. for 1 minute. In this manner, the Pd catalyst coating was formed on the front face and the back face of the transparent substrate.

Thereafter, in the activation treatment, the transparent substrate was immersed in 50 g/l of an aqueous hypophosphorous acid solution for 1 minute. In this manner, both of the front and back faces (exposed face of the catalyst coating provided thereof) of the transparent substrate was subjected to an activation treatment.

In this manner, both of the front and back faces of the transparent substrate were pretreated.

Then, the pretreated transparent substrate was immersed in an electroless nickel plating solution of 50° C. for 3 minutes. In this manner, on both of the front and back faces of the transparent substrate, an underlying metal (first underlying metal and second underlying metal) composed of nickel was formed (ref: FIG. 1B). The surface resistance of the first underlying metal and the back face resistance of the second underlying metal were 0.5 Ω/□.

Then, the transparent substrate having the underlying metals (first underlying metal and second underlying metal) formed on both of the front and back faces was immersed in a copper sulfate plating solution of 23° C., and electrolytic plating was performed with an average electric current density of 0.5 A/dm² for 2 minutes. In this manner, electrode layers (first electrode layer and second electrode layer) composed of copper and having a thickness of 200 nm were formed on the front face of the first underlying metal, and the back face of the second underlying metal (ref: FIG. 1C). The surface resistance of the first electrode layer and the back face resistance of the second electrode layer were 0.1 Ω/□.

The transparent substrate on which the electrode layers (the first electrode layer and the second electrode layer) were formed on both of the front and back sides was immersed in a NiZn plating solution of 30° C., and electrolytic plating was performed with an average electric current density of 0.08 A/dm² for 90 seconds (ref: phantom line in FIG. 1D). In this manner, the black layer composed of NiZn and having a thickness of 50 nm was formed on the front face of the first electrode layer, and on the back face of the second electrode layer.

### Example 3

A laminate for electrode pattern production was produced in the same manner as in Example 2, except that the output of the low pressure mercury lamp was changed to 40 W, and the ultraviolet ray irradiation conditions with the low pressure mercury lamp were changed to 10 minutes and 3332 mJ/cm².

### Example 4

A laminate for electrode pattern production was produced in the same manner as in Example 2, except that the output of the low pressure mercury lamp was changed to 40 W, and the ultraviolet ray irradiation conditions with the low pressure mercury lamp were changed to 3 minutes and 1097 mJ/cm².

### Comparative Example 1

A laminate for electrode pattern production was produced in the same manner as in Example 1, except that the ultraviolet ray irradiation conditions with the low pressure mercury lamp were changed to 15 seconds and 308 mJ/cm².

### Comparative Example 2

A laminate for electrode pattern production was produced in the same manner as in Example 2, except that the ultraviolet ray irradiation conditions with the low pressure mercury lamp were changed to 30 seconds and 632 mJ/cm².

### Comparative Example 3

A laminate for electrode pattern production was produced in the same manner as in Example 2, except that the output of the low pressure mercury lamp was changed to 40 W, and the ultraviolet ray irradiation conditions with the low pressure mercury lamp were changed to 30 seconds and 202 mJ/cm².

### Comparative Example 4

A laminate for electrode pattern production was produced in the same manner as in Example 1, except that the ultraviolet ray irradiation conditions with the low pressure mercury lamp were changed to 30 seconds and 627 mJ/cm².

Evaluation

The following physical properties were measured. The results thereof (excluding SEM images) are shown in Table 1.

### 1. Reflectance of the Front Face of the Underlying Metal

After protecting the black layer, second electrode layer, and second underlying metal disposed on the back side of the transparent substrate with a protection film, the transparent substrate was immersed in a nitric acid/hydrogen peroxide liquid of 40° C. for 10 minutes. In this manner, the black layer, first electrode layer, and first underlying metal disposed on the front side of the transparent substrate were removed (peeled).

Thereafter, the second underlying metal was irradiated from and through the front side of the transparent substrate using a spectrophotometer (V-670, manufactured by JASCO Corporation), and scanning was performed in a measurement range of a wavelength of 1300 to 300 nm, thereby measuring the reflectance of the front face of the second underlying metal. To be specific, the luminous reflectance value Y was regarded as reflectance.

### 2. Roughness Ra of the Back Face of the Underlying Metal

The roughness Ra of the front face of the first underlying metal and the roughness Ra of the back face of the second underlying metal of the transparent substrate before the electrode layer was formed were measured in conformity with JIS B 0601 using a confocal laser scanning microscope (OLS300, manufactured by Olympus Corporation).

### 3. Average Particle Size of Agglomerated Particles (Average Particle Size of Agglomerated Particles of the Metal of the Second Underlying Metal)

The average particle size of the agglomerated particles of metal particles of the second underlying metal was measured.

To be specific, an image of the second underlying metal disposed on the transparent substrate before the second electrode layer was formed was captured using a FIB-SEM composite apparatus (trade name “SMI9200”, magnification used: 100,000×, manufactured by SII NanoTechnology Inc.). From the captured image, the grain boundary of the secondary particles was identified using an image analysis software “Image J”, and thereafter, setting the longitudinal direction of the secondary particle as a diameter, the average value according to the number of the particles in the image was determined (average particle size).

TABLE 1

| | |
|---|---|
| Modification Process | Second underlying metal |

| | Output of low | | | | Average | |
|---|---|---|---|---|---|---|
| | pressure mercury | | | Roughness | secondary | Surface |
| | lamp | Irradiation | | Ra (nm) of | particle size | reflectance |
| | (W) | amount (mJ/cm²) | Type | back face | (μm) | (%) |
| Example 1 | 400 | 1260 | Cu | 199 | 68.2 | 7.9 |
| Example 2 | 400 | 1245 | Ni | 240 | 88.4 | 7.0 |
| Example 3 | 40 | 3332 | Ni | 163 | 47.5 | 11.4 |
| Example 4 | 40 | 1097 | Ni | 127 | — | 14.9 |
| Com. Ex. 1 | 400 | 308 | Cu | 35 | 29.8 | 40.4 |
| Com. Ex. 2 | 400 | 632 | Ni | 89 | — | 25.1 |
| Com. Ex. 3 | 40 | 202 | Ni | 37 | 22.8 | 33.2 |
| Com. Ex. 4 | 400 | 627 | Cu | 77 | — | 36.5 |

### 4. SEM Observation

The back face of the second underlying metal disposed on the transparent substrate before forming the second electrode layer was observed with an SEM.

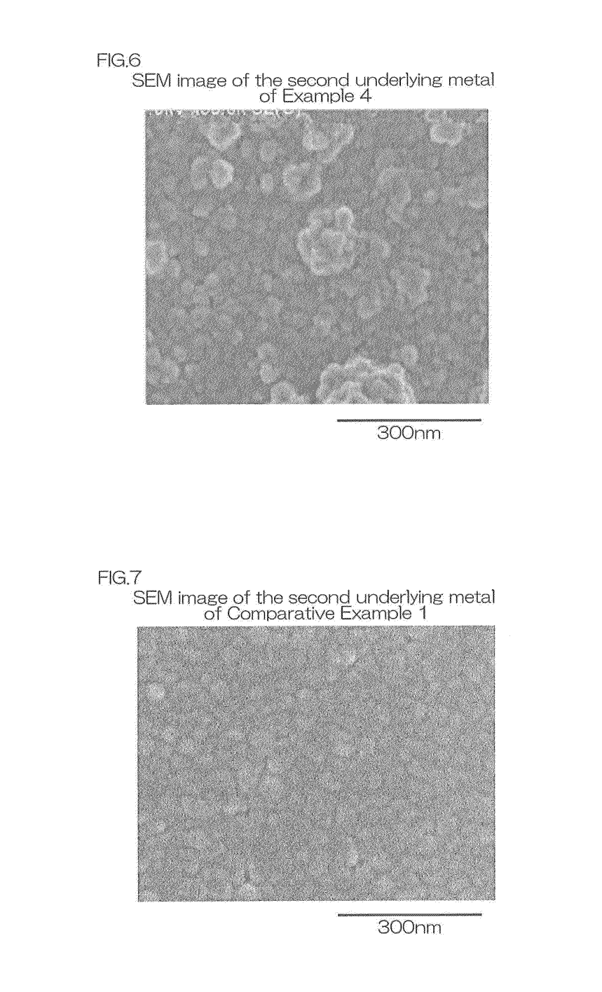

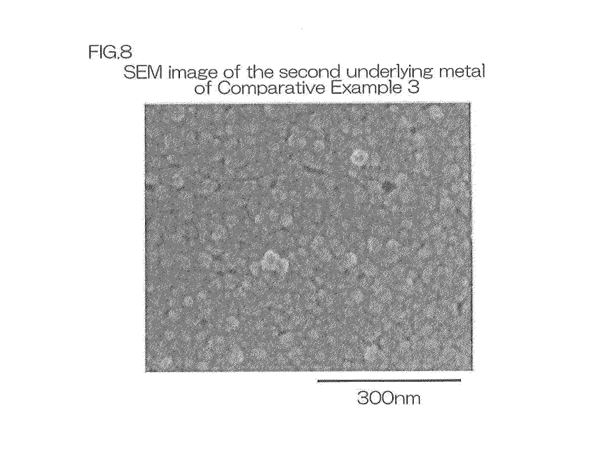

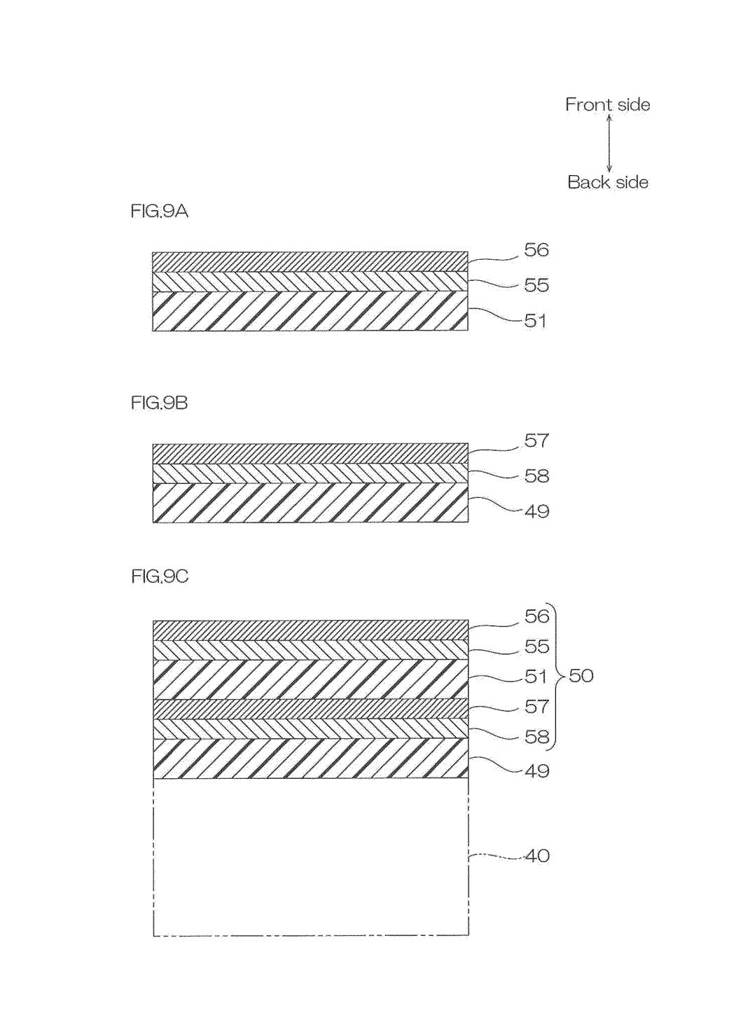

SEM images captured in Examples 1, 2, 4, and Comparative Example 1, 3 are shown in FIGS. 4 to 7.

While the illustrative embodiments of the present invention are provided in the above description, such is for illustrative purpose only and it is not to be construed as limitative. Modification and variation of the present invention which will be obvious to those skilled in the art is to be covered by the following claims.

What is claimed is:

1. A laminate for electrode pattern production, comprising:
a transparent substrate;
an underlying metal disposed on one face in a thickness direction of the transparent substrate, wherein the one face in the thickness direction of the underlying metal has an arithmetical roughness Ra calculated in conformity with JIS B 0601 of 100 nm or more; and
an electrode layer disposed on the one face in the thickness direction of the underlying metal.

2. The laminate for electrode pattern production according to claim 1, wherein the underlying metal includes agglomerated particles made of agglomerated primary particles of metal particles, and
the agglomerated particles have an average particle size of 30.0 nm or more.

3. The laminate for electrode pattern production according to claim 1, wherein the luminous reflectance (value Y) is 20.0% or less, the luminous reflectance measured by using a spectrophotometer, irradiating the underlying metal from the other side in the thickness direction of the transparent substrate through the transparent substrate, and scanning with a wavelength of 300 nm to 1300 nm.

4. The laminate for electrode pattern production according to claim 1, wherein the underlying metal is provided by modifying the one face in the thickness direction of the transparent substrate with one selected from the group consisting of active energy rays, plasma, and laser, and then electrolessly plating the modified transparent substrate.

5. The laminate for electrode pattern production according to claim 1, wherein the underlying metal is also disposed on the other face in the thickness direction of the transparent substrate, and
of the two underlying metals, at least one face in the thickness direction of the underlying metal disposed at one side in the thickness direction of the transparent substrate has an arithmetical roughness Ra of 100 nm or more.

6. A touch panel substrate comprising an electrode pattern formed by patterning the electrode layer and the underlying metal of the laminate for electrode pattern production according to claim 1.

7. An image display device comprising
the touch panel substrate according to claim 6, and
an image display element disposed at one side in the thickness direction of the touch panel substrate.

8. The image display device according to claim 7,
wherein the image display element is a liquid crystal display module.

9. A method for producing a laminate for electrode pattern production, the method comprising the steps of:
preparing a transparent substrate,
modifying one face in the thickness direction of the transparent substrate,
disposing an underlying metal on the modified one face in the thickness direction of the transparent substrate, and
disposing an electrode layer on the one face in the thickness direction of the underlying metal.

10. The method for producing a laminate for electrode pattern production according to claim 9, wherein in the step of modifying one face in the thickness direction of the transparent substrate, the transparent substrate is modified by one selected from the group consisting of active energy rays, plasma, and laser.
